(19) United States
(12) Patent Application Publication
(10) Pub. No.: US 2013/0099202 A1
(43) Pub. Date: Apr. 25, 2013

(54) SUPPRESSION OF RELAXATION BY LIMITED AREA EPITAXY ON NON-C-PLANE (In,Al,B,Ga)N

(71) Applicant: The Regents of the University of California, Oakland, CA (US)

(72) Inventors: Matthew T. Hardy, Goleta, CA (US); Shuji Nakamura, Santa Barbara, CA (US); Steven P. DenBaars, Goleta, CA (US); James Stephen Speck, Goleta, CA (US)

(73) Assignee: THE REGENTS OF THE UNIVERSITY OF CALIFORNIA, Oakland, CA (US)

(21) Appl. No.: 13/659,125

(22) Filed: Oct. 24, 2012

Related U.S. Application Data
(60) Provisional application No. 61/550,822, filed on Oct. 24, 2011.

(51) Int. Cl. H01L 29/15; H01L 21/20

(52) U.S. Cl. 257/14; 438/504; 257/E29.078; 257/E21.09

(57) ABSTRACT

An (AlInGaN) based semiconductor device, including one or more (In,Al)GaN layers overlying a semi-polar or non-polar III-nitride substrate or buffer layer, wherein the substrate or buffer employs patterning to influence or control extended defect morphology in layers deposited on the substrate; and one or more (AlInGaN) device layers above and/or below the (In,Al)GaN layers.

### CROSS REFERENCE TO RELATED APPLICATIONS

This application claims the benefit under 35 U.S.C Section 119(e) of U.S. Provisional Patent Application Ser. No. 61/550,822 filed on Oct. 24, 2011, by Matthew T. Hardy, Shuji Nakamura, Steven P. DenBaars, and James S. Speck, entitled “SUPPRESSION OF RELAXATION BY LIMITED AREA EPITAXY ON NON-C-PLANE (In,Al,B,Ga)N,” attorney's docket number 30794.431-US-P1 (2012-237-1), which application is incorporated by reference herein.

This application is related to co-pending and commonly assigned U.S. Utility patent application Ser. No. 13/281,767 filed on Oct. 26, 2011, by James S. Speck, Anurag Tyagi, Alexey Romanov, Shuji Nakamura, and Steven P. DenBaars, entitled “VICINAL SEMIPOLAR III-NITRIDE SUBSTRATES TO COMPENSATE TILT FO RELAXED HETERO-EPITAXIAL LAYERS,” attorney' docket number 30794.386-US-U1 (2010-973), which application claims the benefit under 35 U.S.C. Section 119(e) of co-pending and commonly-assigned Provisional Patent Application Ser. No. 61/406,899, filed on Oct. 26, 2010, by James S. Speck, Anurag Tyagi, Alexey Romanov, Shuji Nakamura, and Steven P. DenBaars, entitled “VICINAL SEMIPOLAR III-NITRIDE SUBSTRATES TO COMPENSATE TILT FO RELAXED HETERO-EPITAXIAL LAYERS,” attorney' docket number 30794.386-US-P1 (2010-973), which applications are incorporated by reference herein.

### BACKGROUND OF THE INVENTION

1. Field of the Invention

This invention relates to a method of fabricating devices, by suppression of relaxation by limited area epitaxy on non-c-plane (In,Al,B,Ga)N, and devices fabricated using the method.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Despite recent progress, the performance of green light emitting diodes (LEDs) and laser diodes (LDs) is much lower than equivalent devices emitting in blue or violet regimes. Active regions operating in the green regime require Indium (In) compositions in the quantum wells (QWs) around 30%. Due to the large lattice mismatch between InN and GaN of around 10%, such structures must be grown at very high strain (3% for In_{0.3}Ga_{0.7}N), degrading crystal quality and leading to large piezoelectric induced electric fields in the quantum wells. Stress relaxation also limits the composition and thickness of InGaN waveguiding layers in LDs [1].

For traditional planar c-plane and nonpolar strained heteroepitaxy, stress relaxation typically does not occur via slip due to the absences of resolved shear stress on the c-plane, which is the most favorable slip system. However, c-plane slip has been observed on (20-21) and (11-22) semipolar orientations, which have significant resolved shear stress on the c-plane [2]. Additionally, slip on the prismatic m-plane system has been observed for growth on non-polar m-plane and semipolar (11-22), (20-21), and (30-3-1) planes [3]. This has important consequences for devices grown on non-c-plane orientations.

### SUMMARY OF THE INVENTION

To overcome the limitations in the prior art described above, and to overcome other limitations that will become apparent upon reading and understanding the present specification, the present invention discloses a III-nitride based semiconductor device structure, comprising a substrate, or one or more III-nitride layers on the substrate, wherein the substrate or III-nitride layers include patterning that reduces crystal defects in subsequently deposited III-nitride device layers, as compared to crystal defects in III-nitride layers formed on an un-patterned substrate or un-patterned III-nitride layer. The III-nitride layers can be semi-polar or non-polar layers.

One or more of the III-nitride device layers can be above, below, or above and below, the III-nitride layers.

The patterning can include one or more etched mesas.

A Limited Area Epitaxy (LAE) substrate can be prepared by patterning and etching mesas into the GaN substrate or buffer layer. The device can then be directly re-grown on the un-etched regions of the surface. The mesa size, shape and orientation affect the onset of relaxation of the device layers.

One or more of a thickness and composition of the III-nitride layers can be high enough such that a film, comprising one or more of the III-nitride layers and the III-nitride device layers, has a thickness near or greater than the film's critical thickness for relaxation without the patterning.

One or more of the III-nitride device layers above the patterning can comprise a thickness greater than a thickness of similar III-nitride device layers deposited on the substrate or III-nitride layers without the patterning. The device can be a fully coherent device with the III-nitride device layers thicker than a normal relaxation thickness limit.

The patterning can form a pattern with one or more dimensions such that a thickness of a III-nitride device layer at a given composition, before relaxation, is increased by a factor of at least 4. The pattern can comprise one or more stripes and a width of each of the stripes in the pattern is 1-50 μm.

The patterning can form a pattern and an orientation of the pattern is such that a thickness of a III-nitride device layer at a given composition, before relaxation, is increased by a factor of at least 4.

The patterning can form a pattern wherein the pattern is oriented parallel to an in-plane projection of a c-direction of the substrate or III-nitride layers.

The patterning can be performed on a layer subsequently grown on the III-Nitride substrate or the III-nitride layers.

The patterning can reduce or prevent the formation of misfit dislocation lines parallel to an a-direction of the III-nitride device layers.

The patterning can reduce or prevents the formation of misfit dislocation lines inclined with respect to an a-direction of the III-nitride device layers.

The patterning can comprise a hard mask.

The III-nitride device layers can be grown on an un-patterned region of the III-nitride layers or on an un-patterned region of the wafer comprising the substrate or the III-nitride layers.

The III-nitride device layers can be the layers of a laser diode, including cladding layers, waveguiding layers and an active region.

The III-nitride device layers can be layers of a light emitting diode, solar cell or electronic device, such as a transistor.

The III-nitride device layers can comprise a quantum well active region with an indium composition of at least 30%, or an indium composition sufficient to emit light with a peak intensity corresponding to at least green light.

The substrate can be a Gallium Nitride substrate and the III-nitride device layers can comprise n-type and p-type InGaN waveguiding layers that are coherently grown with a thickness of at least 100 nanometers and an Indium composition of at least 10%; a multi quantum well active region, between the waveguiding layers, with InGaN quantum wells, wherein an indium composition of the quantum wells is at least 10%; and n-type and p-type Gallium Nitride layers, wherein the n-type and p-type waveguiding layers are between the n-type and p-type GaN layers.

The substrate can be Gallium Nitride having a threading dislocation density of 10⁶ cm⁻² or more; and the patterning can be such that a misfit dislocation density in the III-nitride device layers is 10⁴ cm⁻² or less and located away from an active region of the device.

The present invention further discloses a method of fabricating a III-nitride based semiconductor device, comprising patterning a substrate, or one or more III-nitride layers on the substrate, to influence or control extended defect morphology in subsequently deposited III-nitride device layers; and growing one or more III-nitride layers, as the subsequently deposited III-nitride device layers, on the patterned substrate or III-nitride layers.

For example, the present invention has demonstrated In_{0.06}Ga_{0.94}N layers on (20-21) semipolar free-standing GaN substrates, grown up to 175 nm thickness without any sign of relaxation, where (h_{c}) is 45 nm and actual relaxation typically begins at around 100 nm. Additionally, the present invention has grown full AlGaN-cladding-free (ACF) LD structures with 50 nm thick n- and p-In_{0.08}Ga_{0.92}N waveguiding layers without relaxation (when planar structures with n-/p-In_{0.08}Ga_{0.92}N relax before 35 nm thickness). These effects should be similar for AlGaN layers, extending the critical thickness of n-/p-AlGaN cladding without relaxation, as well as other devices, such as solar cells and multi quantum well (MQW) LEDs which utilize thick, highly strained layers or superlattice type structures with high average strain.

### BRIEF DESCRIPTION OF THE DRAWINGS

Referring now to the drawings in which like reference numbers represent corresponding parts throughout:

FIG. 1 shows (a) Scanning Electron Microscope (SEM), (b) Cathodoluminescence (CL) images of 175 nm thick In_{0.06}Ga_{0.94}N grown on 20 μm wide (left) and 5 μm wide (right) stripe mesas etched 1 μm into a bare GaN substrate, orientated perpendicular to the a-direction.

FIG. 1 shows (c) SEM and (d) CL images from the same sample as FIG. 1(a)-(b), showing the impact of orientation dependence in the two orthogonal in-plane directions for 5 μm wide mesas.

FIG. 1 shows (e) SEM and (f) CL images for 300 nm thick In_{0.06}Ga_{0.94}N with 20 μm, and 5 μm stripes.

FIG. 1 shows (g) SEM and (h) CL images for the same orientation test pattern.

FIG. 1 shows (i) CL image of a 110 thick planar In_{0.06}Ga_{0.94}N sample showing the onset of c-plane slip and (j) 200 nm In_{0.06}Ga_{0.94}N sample showing both c-plane and m-plane slip.

FIG. 2 shows (a) SEM and (b) CL images of a 300 nm In_{0.06}Ga_{0.94}N grown on a 2 μm wide test pattern to show the effect of orientation, and (c) SEM and (d) CL images of the same sample showing stripe width dependence, wherein the widths of the fingers are (left to right) 1.0, 1.2, 1.4, 1.6, 1.8, 2.0, 2.5, 3.0 and 4.0 μm.

FIG. 3 shows fluorescence micrographs of full ACF Laser Diode (LD) structures, wherein (a), (b), and (c) are standard planar samples, (d), (e), and (f) are LAE LD structures with 2.5, 5, 10 and 15 μm mesas, (a) and (d) have 25 nm n- and p-In_{0.08}Ga_{0.92}N waveguiding layers, (b) and (e) have 35 nm thick n- and p-In_{0.08}Ga_{0.92}N waveguiding layers, and (c) and (f) have 50 nm thick n- and p-In_{0.08}Ga_{0.92}N waveguiding layers.

FIG. 3(g) illustrates a device structure measured in FIGS. 3(a)-(f) and FIG. 4.

FIG. 4 shows a fluorescence micrograph of an ACF LD structure with 35 nm n- and p-In_{0.08}Ga_{0.92}N waveguiding layers, showing the transition from a stripe LAE region (bottom half) with no evidence of MD formation, to a planar region of the wafer (top half) where dark lines parallel to the a-direction indicate MD formation.

FIG. 5 are cross-sectional schematics of (a) etched mesa LAE with device layers re-grown on top or in between etched mesas, (b) ridge waveguide LDs fabricated on top of etched mesa LAE, and (c) LAE on top of an intermediate layer.

FIG. 6 illustrates an example of etched mesa substrates leading to LAE.

FIG. 7 illustrates an example of a device structure.

FIG. 8 is a flowchart illustrating a method of fabricating a device.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

One technique to avoid relaxation by glide of pre-existing threading dislocations (TDs) is to limit the number of TDs available. The most obvious way to do this is to use a substrate with very low TD density. If such substrates are not available, then access to existing TDs can be limited locally by etching mesas on a substrate and then growing on the mesas—known as limited area epitaxy (LAE). The TDs cannot cross the mesa wall, limiting relaxation by TD glide to the TDs on the mesa itself. The effect breaks down when sufficient strain energy accumulates to allow nucleation of new TDs on mesa sidewall roughness or sidewall facets.

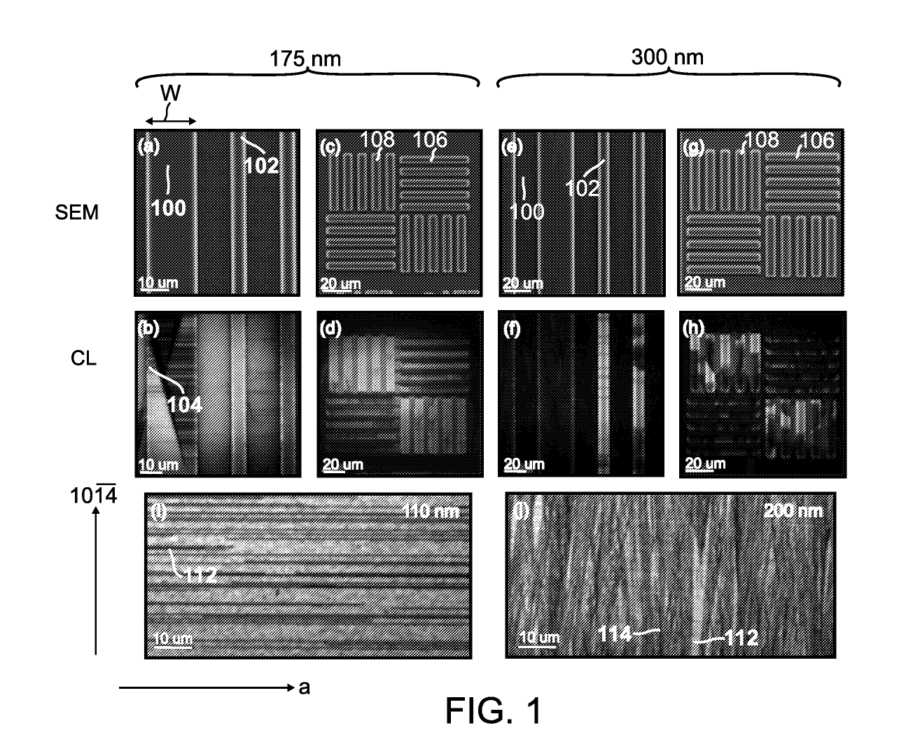

A series of different mesa structures were fabricated on a (20-21) freestanding GaN substrate, to examine the effect of geometry and orientation on LAE suppression of relaxation. FIGS. 1-4 illustrate measurements of (20-21) layers on a (20-21) substrate.

FIG. 1 compares two InGaN samples overgrown on various etched mesas. FIG. 1 (a) and (b) are top view SEM and CL images of 20 μm wide (w) stripe mesas 100 and 5 μm wide (w) stripe mesas 102 of 175 nm thick In_{0.06}Ga_{0.94}N. FIG. 1 (e) and (f) are similar images for the samples with mesas 100, 102 of 300 nm thick In_{0.06}Ga_{0.94}N. Clearly, narrower ridges have reduced dark line defects 104, wherein the majority of the 175 nm thick 5 μm wide mesa 102 is entirely free of Misfit Dislocations (MDs).

FIG. 1 (c) and (d) are top view SEM and CL images of a series of 5 μm wide mesas (of 175 nm thick In_{0.06}Ga_{0.94}N) orientated parallel 106 to, and orthogonal 108 to, the a-direction.

FIG. 1(g) and (h) are similar top view images for the 300 nm thick In_{0.06}Ga_{0.94}N sample. Mesas oriented perpendicular to the a-direction have much fewer Misfit Dislocation (MD) lines 104. This is reasonable given the slip on the c-plane forms MD lines parallel to the a-direction.

FIG. 1(i) and (j) are top view images of planar (no Limited Area Epitaxy or no mesas) reference samples at the same composition, with In_{0.06}Ga_{0.94}N thicknesses of 110 nm and 200 nm, respectively. The planar samples have much higher MD densities, with FIG. 1(i) showing the onset of c-plane slip 112 and (j) showing advanced c-plane 112 and m-plane slip 114.

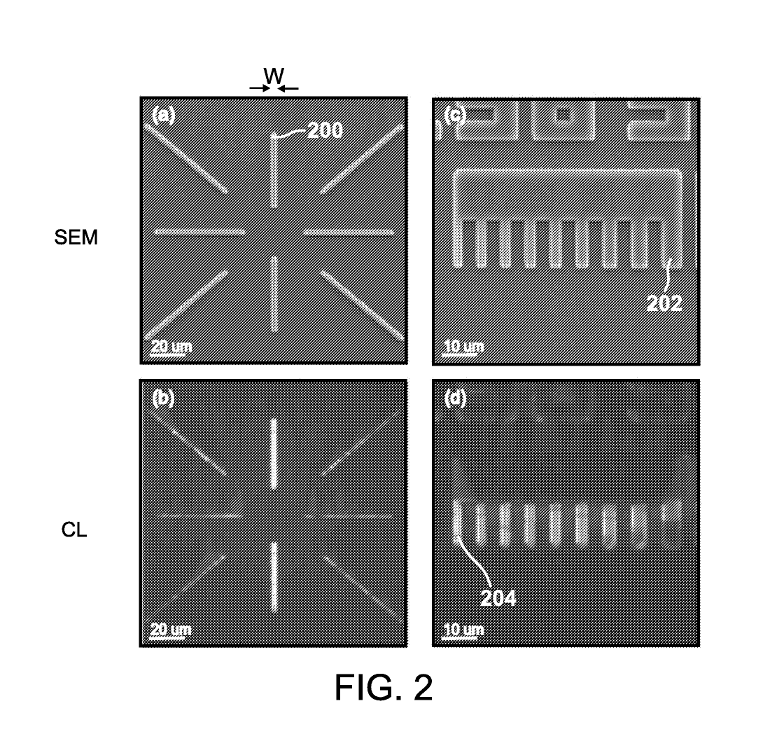

FIG. 2 (a) and (b) are top view SEM and CL images, respectively, showing the orientation dependence of the mesas for a 2 μm wide (w) structure, wherein structure 200 oriented perpendicular to the a-direction has fewest MD lines.

FIG. 2(c) and (d) are top view SEM and CL showing the width w dependence. The fingers 202 show reduced MD density with decreasing width w, with only a few sparse MD lines 204 for mesa widths below 2 μm.

Full ACF LD structures were grown using horizontal-flow MOCVD on substrates patterned with 2.5, 5, 10 and 15 μm wide stripes oriented perpendicular to the a-direction. In_{0.08}Ga_{0.92}N n- and p-waveguiding layers with thicknesses (on each side) of 25, 35 and 50 μm were grown and examined with fluorescence microscopy.

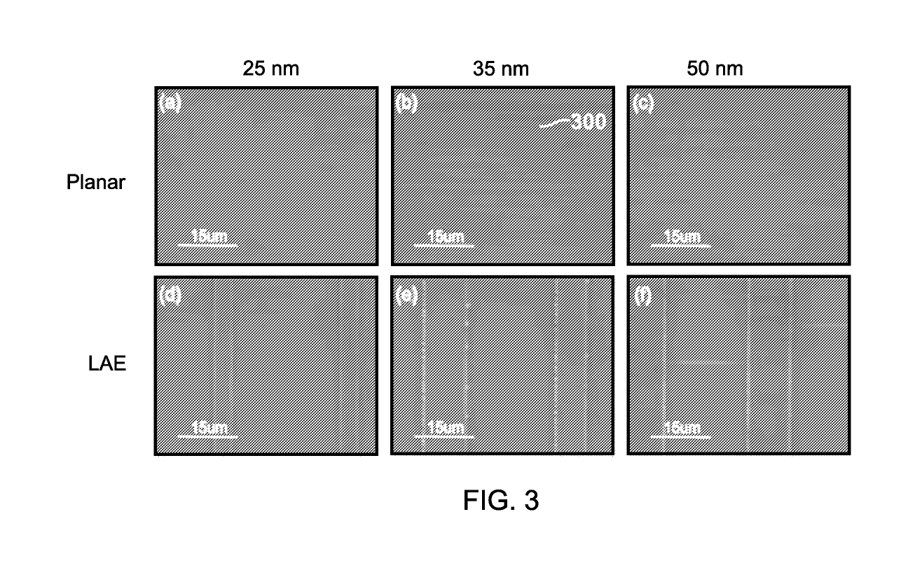

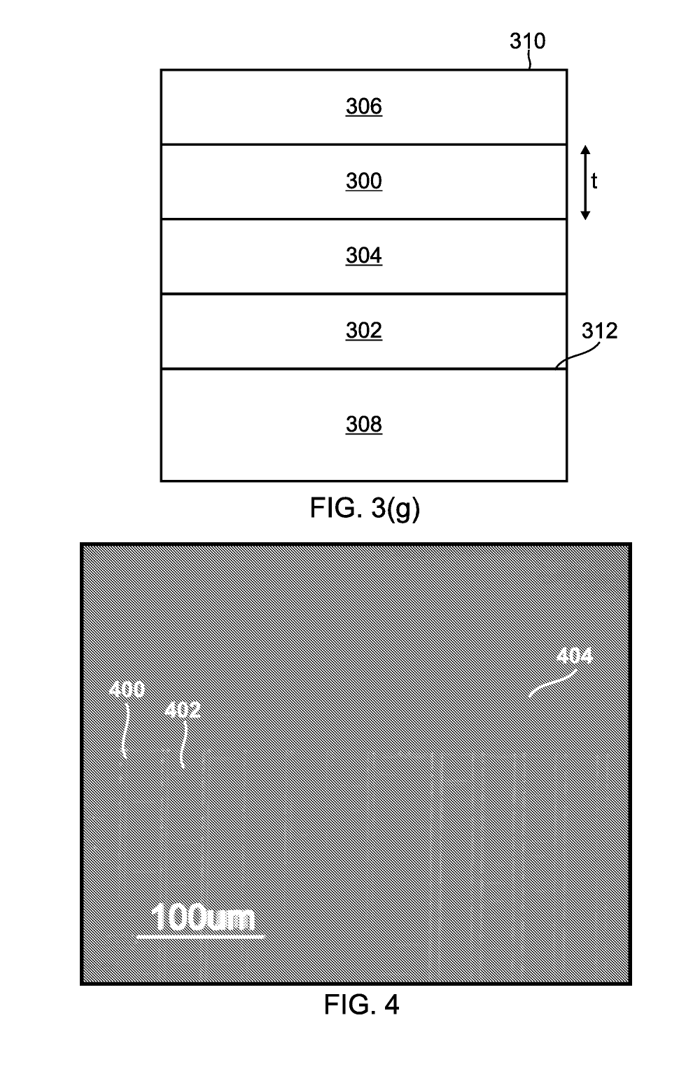

FIG. 3(a)-(c) show fluorescence measurements of planar samples with 25, 35 and 50 nm In_{0.08}Ga_{0.92}N Separate Confinement Heterostructure (SCH) layers, respectively, and FIG. 3(d)-(f) show fluorescence measurements of corresponding LAE samples with 25, 35 and 50 nm SCH layers. No identifiable MD lines were observed in any of the LAE samples, while the 35 and 50 nm planar samples had clear dark lines 300 parallel to the a-direction.

FIG. 3(g) is a cross-sectional schematic of the device structure measured in FIG. 3(a)-(f). The device structure comprises an In_{0.08}Ga_{0.92}N p-type waveguiding layer 300 and an n-type In_{0.08}Ga_{0.92}N waveguiding layer 302 with thicknesses t on each side of a quantum well active region 304. The structure is capped with a p-type GaN layer 306, and the layers 300-306 are formed on a (20-21) freestanding GaN substrate 308.

It is clear from FIG. 4 that the reduction in MD formation applies not only to the mesas 400, but to the etched regions 402 in between (FIG. 4 measures fluorescence from the same structure as shown in FIG. 3(g)). MD lines 404 are visible in the planar region.

In FIG. 3(a)-(f) and FIG. 4, fluorescence was measured from the top surface 310 of the p-GaN 306.

In the case of FIG. 3(d)-(f), and the upper portion of FIG. 4, the (20-21) surface 312 was etched to fabricate patterning for the LAE, whereas for the planar structures, the surface 312 was not patterned.

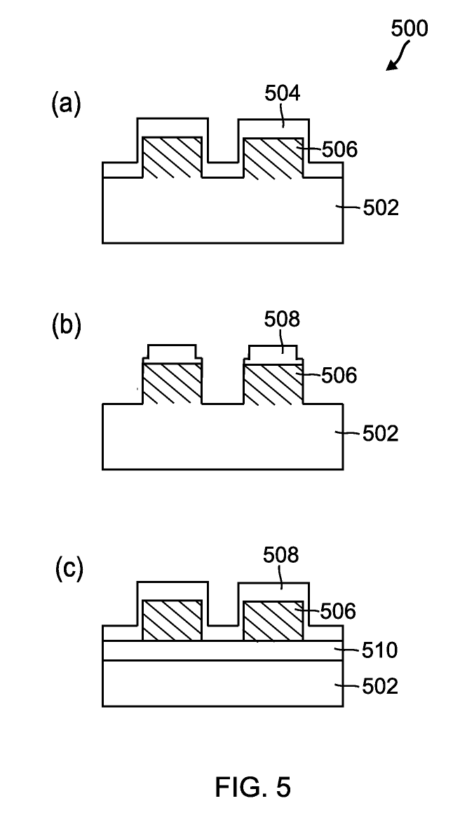

A standard broad area or ridge waveguide laser diode can then be fabricated, either aligned on top of the mesas, or in between. The patterning can also be done on an intermediate layer, for example, a relaxed buffer layer. This would allow relaxation in the intermediate layer, then suppress relaxation in layers grown by LAE in a subsequent re-growth after patterning. Examples of each are given in FIG. 5.

FIG. 5(a) illustrates an (AlInGaN) or III-nitride based semiconductor device 500, comprising a semi-polar or non-polar III-nitride substrate or III-nitride buffer layer 502 (e.g., III-nitride buffer layer on a hetero-substrate). The substrate 502 or buffer layer employ patterning to influence or control extended defect morphology in subsequently deposited AlInGaN device layers or Limited Area Epitaxy (LAE) device layers 504. The patterning comprises a patterned mesa 506 remaining after an etch of the substrate or buffer 502.

FIG. 5(b) illustrates the device layers 504 are etched to form the etched ridge waveguide laser layers 508 of a laser diode, including cladding layers, waveguiding layers and an active region.

FIG. 5(c) illustrates the (AlInGaN) based semiconductor device 500, comprising one or more (In,Al)GaN or III-nitride layers 510 overlying the semi-polar or non-polar III-nitride substrate 502 or buffer layer. The (In,Al)GaN or III-nitride 510 layers employ patterning to influence or control extended defect morphology in the subsequently deposited AlInGaN LAE device layers 504.

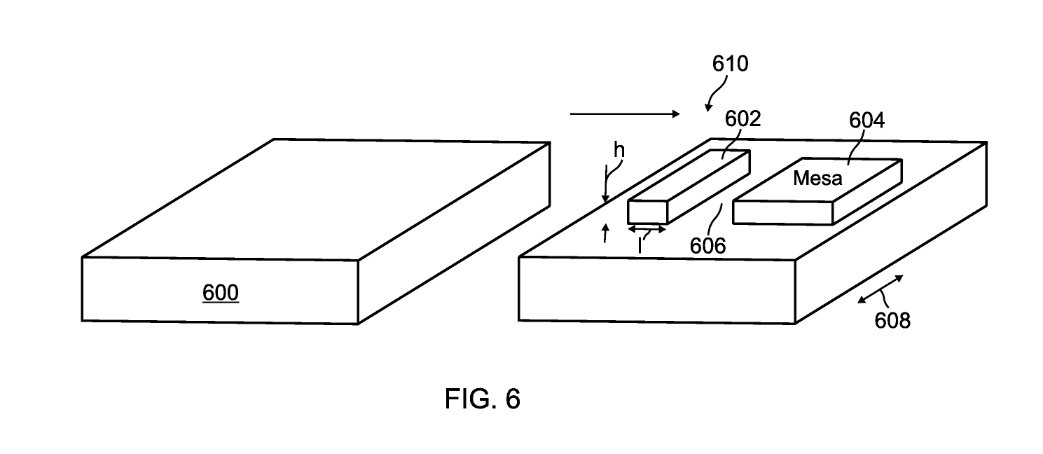

FIG. 6 illustrates an example of etched mesa substrates leading to LAE. In a first step, a bare substrate 600 is etched to form mesas or stripes 602. In a second step, a device is regrown on the top surface 604 of the mesa 602 and/or on the surface 606 in between the mesas 602. The mesa lateral size l, height, h and orientation 608 affect relaxation. The patterning can form a pattern 610. Using the present invention, fully coherent devices can be created with layers well past normal relaxation limits.

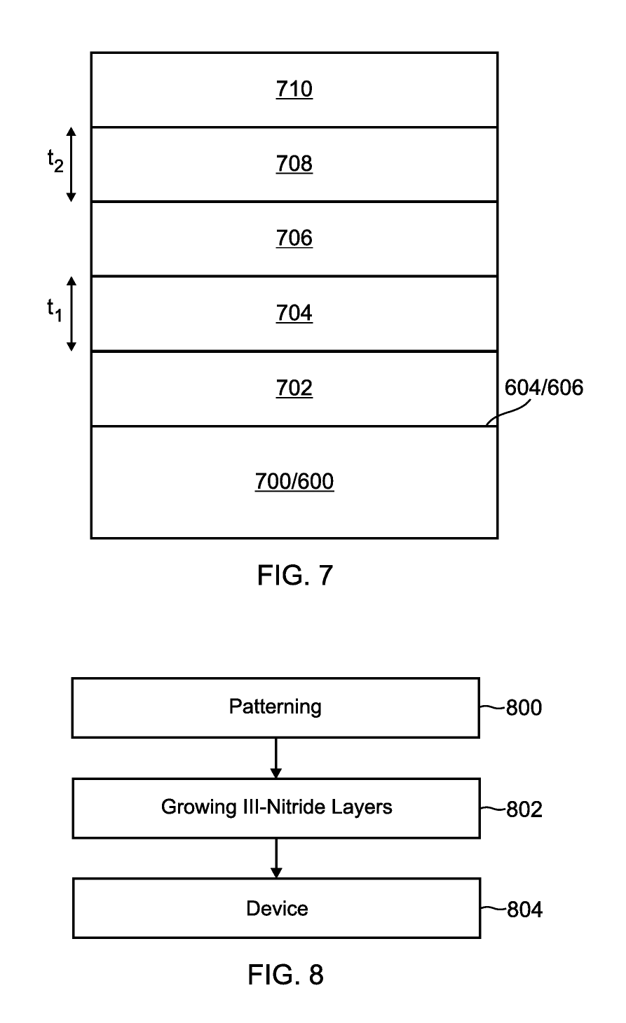

FIG. 7 illustrates an example of a device structure that can be deposited on the patterned non-polar or semi-polar surface 604/606 of the substrate 600. FIG. 7 illustrates a Gallium Nitride substrate 700/600 and an n-type GaN layer 702 (e.g., cladding layer) on or above the substrate 700. An n-type InGaN waveguiding layer 704 is on or above the GaN layer 702, wherein the n-type InGaN waveguiding layer 704 is coherently grown with a thickness t₁ of at least 100 nanometers and an Indium composition of at least 10%. A multi quantum well active region 706 is on or above the n-type waveguiding layer 704, comprising InGaN quantum wells and GaN barriers, wherein an indium composition of the quantum wells is at least 10%. A p-type InGaN waveguiding layer 708 is on or above the active region 706, wherein the p-type InGaN waveguiding layer 708 is coherently grown with a thickness t₂ of at least 100 nanometers and an Indium composition of at least 10% (this is the composition/thickness used for relaxed waveguiding layers). For a planar structure, the thickness is limited to 25 nm of In_{0.08}Ga_{0.92}zN. In one embodiment of a LAE Laser Diode, the thickness may be limited to 50 nm of In_{0.08}Ga_{0.92}N (for t₁ and t₂)−t₁ and t₂ are normally equal, but they don't have to be.

A p-type Gallium Nitride layer 710 (e.g., cladding) is on or above the p-type waveguiding layer 708. Other layers, as known in the art, can also be added (e.g., electron blocking layers between the active region 706 and p-type waveguide layer 708, contact layers, etc.)

Another example of device structure fabricated according to one or more embodiments of the invention is described in [5].

### Process Steps

FIG. 8 illustrates a method of fabricating a III-nitride based semiconductor device, comprising the following steps (referring also to FIG. 1, 2, 5, 6, and FIG. 7 as examples of devices fabricating using the method of FIG. 8).

Block 800 represents patterning a substrate 502, 600, 700 (e.g., III-nitride substrate, Gallium Nitride substrate, semipolar or nonpolar GaN substrate), or one or more III-nitride layers 510 (e.g., template) on the substrate 502, to influence or control extended defect morphology in subsequently deposited III-nitride device layers 504, 702-710. The III-nitride layer(s) 510 can comprise (In,Al)GaN, e.g., Gallium and Aluminum or Gallium and Indium, for example. The III-nitride layer 510 can comprise a buffer layer.

The substrate can be Gallium Nitride or III-nitride having a threading dislocation density of 10⁶ cm⁻² or more. The stacking fault density in the substrate can be low enough to be hard to observe, e.g., below 10 cm⁻¹.

The patterning used to control the extended defect morphology can include one or more etched mesas 506 (e.g., formed by etching mesas 506 in the substrate 502 or III-nitride layers 510).

The patterning used to control the extended defect morphology can comprise a mask (e.g., hard mask), such as but not limited to, SiO₂, Si₃N₄ or AN (e.g., formed by depositing the mask on the substrate or III-nitride layers).

The patterning can form a pattern 610 comprising one or more dimensions l, h used to control the extended defect morphology. For example, the pattern can comprise one or more stripes 602 wherein a width w or l of each of the stripes 602 in the pattern is 1-50 μm.

An orientation 608 of the pattern 610 can be used to control the extended defect morphology. For example, the pattern can be oriented parallel to an in-plane projection of a c-direction of the III-nitride substrate 502 or III-nitride layers 510. For example, the longest dimension of the stripes 602 can be oriented 608 perpendicular to the in-plane projection of the c-direction. For example, the longest dimension of the stripes 602 can be oriented 608 perpendicular to the a-direction (as shown by FIG. 1(d) and FIG. 2(a) for a 20-21 oriented structure).

The patterning 610 can be used to reduce or prevent the formation of misfit dislocation lines parallel to, or inclined with respect to, an a-direction of the III-nitride layers 702-710.

The patterning can be performed on a layer 702-710 subsequently grown on the III-Nitride substrate 700 or the buffer layer. For example, previously deposited layers can be unpatterned.

Block 802 represents growing one or more III-nitride or AlInGaN layers 702-710, as the subsequently deposited III-nitride device layers, on the patterned substrate 600, 700 or on the III-nitride layers 510. The III-nitride layers 702-710 can be semi-polar or non-polar layers. The one or more (AlInGaN) device layers can be above (active region 706, waveguide layer 708, GaN layer 710 and/or below (GaN layer 702) the (In,Al)GaN layers 510).

A thickness t₁ or t₂ and/or composition of one or more of the III-nitride layers 510 and/or III-nitride device layers 702-710 can be high enough such that a film, comprising one or more of, or all of, the III-nitride layers 510 and/or one or more of, or all of, the III-nitride device layers 702-710, has a thickness near or greater than the film's critical thickness for relaxation (e.g. greater than the critical thickness for relaxation without the patterning). The present invention can apply to any layer 702-710 having a thickness that is at the layer's critical thickness, or having a thickness greater than the layer's 702-710 critical thickness.

The patterning 506, 610 can be such that one or more of, or all of, the III-nitride device layers 702-710 above the patterning 506, 610 can comprise a thickness tᵢ or t₂ greater than a thickness of similar/corresponding III-nitride device layers deposited on the substrate or III-nitride layers without the patterning 610, 506. The device can be a fully coherent device with the III-nitride device layers 702-710 thicker than a normal relaxation thickness limit.

The patterning 506, 610 can increase a thickness of one or more of, or all of, the III-nitride device layers 702-710 at a given composition, before relaxation, e.g., by a factor of at least 4. For example, one or more of the III-nitride device layers 702-710 can be coherent and one or more of the layers 702-710 can have a thickness at least four times the Matthews Blakeslee critical thickness for the III-nitride device layer 702-710 (e.g., as defined without the patterning 506, 610).

The III-nitride device layers 504, 704, 706, 708 can comprise an indium composition of at least 7%, at least 10%, at least 16%, or at least 30%, for example. The III-nitride device layer 706 can comprise a quantum well active region with an indium composition sufficient to emit light with a peak intensity corresponding to at least green light (e.g., InGaN). The quantum wells (e.g., InGaN) can have a thickness greater than 4 nanometers (e.g., 5 nm, at least 5 nm, or at least 8 nm, for example). However, the quantum well thickness may also be less than 4 nm, although it is typically above 2 nm thickness. The number of periods of quantum wells in the active region 706, can also vary, e.g., at least two periods, at least three periods, etc., or sufficient number of periods such that the active region has a thickness greater than the critical thickness. Relaxation would occur (without LAE) if the individual QW thickness/composition exceeded the critical thickness, or if the total thickness/average composition of the entire MQW stack (QWs and barriers) exceeded its critical thickness.

The device comprising layers 702-710, or the active region 706, can be free of misfit dislocations. The patterning can be such that a misfit dislocation density in the III-nitride device layers is 10⁴ cm⁻² or less. The misfit dislocations can be restricted to regions away from the active region 706, for example, at interfaces with the substrate 700 or cladding layers 702, 710. For example, some of the device layers 706 can be grown coherently, and some of the layers can be relaxed or partially relaxed (e.g., waveguiding layers 704, 708 can be relaxed).

The III-nitride device layers 702-710 can be grown on an un-patterned region of the III-nitride layers 510, or on an un-patterned region 606 of the wafer comprising the substrate 600, the buffer, and the III-nitride layers 510.

The device layers 504 can be the layers of a laser diode, including cladding layers, waveguiding layers and an active region. However, the device layers 504 can be layers of any optoelectronic device, such as a light emitting diode, solar cell, or of an electronic device, such as a transistor.

Block 804 represents the end result of the method, a III-nitride based semiconductor device 500, comprising a substrate 502, or one or more III-nitride layers 510 on the substrate 502 including patterning 506 to influence or control extended defect morphology (e.g., reduce crystal defects such as threading dislocations, stacking faults, misfit dislocations) in subsequently deposited III-nitride device layers 504, wherein the III-nitride device layers 504 are semi-polar or non-polar layers. The crystal defects can be reduced as compared to crystal defects in III-nitride layers deposited without the patterning of the substrate 502 or III-nitride layers 510, or as compared to crystal defects in III-nitride layers deposited on an un-patterned substrate 502 or un-patterned template 510.

In one example, the substrate is a Gallium Nitride substrate 700 and the III-nitride device layers 702-710 comprise (1) n-type and p-type InGaN waveguiding layers 704, 708 that are coherently grown with a thickness of at least 100 nanometers and an Indium composition of at least 10%, (2) a multi quantum well active region 706, between the waveguiding layers 704, 708, with InGaN quantum wells and GaN barriers or AlGaN barriers, wherein an indium composition of the quantum wells is at least 10%, and (3) n-type and p-type Gallium Nitride layers 702, 710, wherein the n-type and p-type waveguiding layers 704/708 are between the n-type and p-type GaN layers 702, 710. Additional layers (e.g., contacts) can be deposited as known in the art.

Advantages and Improvements

The present invention allows layers to be grown out to at least four times (4×) the Matthews-Blakeslee equilibrium thickness (h_{c}), without relaxation by threading dislocation glide using limited area epitaxy (LAE). This technique is particularly well suited to laser diodes where the composition and thickness of cladding and waveguiding layer is limited by relaxation.

The present invention will allow LDs with higher composition and/or thickness cladding and/or waveguiding layers, leading to higher confinement factor and lower threshold current density. Greater flexibility in waveguide design may also allow greater control of the far field pattern.

Other strained layer devices, such as LEDs, solar cells, and transistors, can also benefit from the present invention. Solar cells, in particular, require thick absorbing regions with high composition InGaN layers to capture light up into the green region of the solar spectrum. The present invention can help prevent the relaxation and formation of MDs in the device active region.

Additionally, blue LEDs show a reduction in efficiency droop for increased numbers of quantum wells (QWs). The present invention can help prevent MD formation in the active region, and increase the total MQW thickness limits.

The present invention has demonstrated both single layers and full LD structures with greatly enhanced effective critical thickness. The present invention expands the accessible thickness/composition range available in non-c-plane devices, increasing the thickness at a given composition before relaxation by a factor of at least 4×. This opens up new design space for waveguiding in LDs, potentially allowing higher performance or higher efficiency devices. Application towards solar cells should improve external quantum efficiency over a wider wavelength range, by allowing thicker, higher composition absorbing regions.

### Nomenclature

The terms “(AlInGaN)” “(In,Al)GaN”, or “GaN” as used herein (as well as the terms “III-nitride,” “Group-III nitride”, or “nitride,” used generally) refer to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

Many (Ga,Al,In,B)N devices are grown along the polar c-plane of the crystal, although this results in an undesirable quantum-confined Stark effect (QCSE), due to the existence of strong piezoelectric and spontaneous polarizations. One approach to decreasing polarization effects in (Ga,Al,In,B)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of Group-III (e.g., gallium) and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero l Miller index. Subsequent semipolar layers are equivalent to one another, so the crystal will have reduced polarization along the growth direction.

For a layer X grown on a layer Y, for the case of coherent growth, the in-plane lattice constant(s) of X are constrained to be the same as the underlying layer Y. If X is fully relaxed, then the lattice constants of X assume their natural (i.e. in the absence of any strain) value. If X is neither coherent nor fully relaxed with respect to Y, then it is considered to be partially relaxed. In some cases, the substrate might have some residual strain.

The equilibrium critical thickness corresponds to the case when it is energetically favorable to form one misfit dislocation at the layer/substrate interface.

Experimental, or kinetic critical thickness, is always somewhat or significantly larger than the equilibrium critical thickness. However, regardless of whether the critical thickness is the equilibrium or kinetic critical thickness, the critical thickness corresponds to the thickness where a layer transforms from fully coherent to partially relaxed.

Another example of critical thickness is the Matthews Blakeslee critical thickness.

Throughout the disclosure, layers that are on an underlying layer can be on, above, or overlying the underlying layer, for example.

### REFERENCES

The following references are incorporated by reference herein.
[1] A. Tyagi, F. Wu, E. C. Young, A. Chakraborty, H. Ohta, R. Bhat, K. Fujito, S. P. DenBaars, S. Nakamura and J. S. Speck, Appl. Phys. Lett. 95, p. 251905 (2009).
[2] E. C. Young, C. S. Gallinat, A. E. Romanov, A. Tyagi, F. Wu and J. S. Speck, Appl. Phys. Express 3, p. 111004 (2010).
[3] S. Yoshida, T. Yokogawa, Y. Imai, S. Kimura, O. Sakata, Appl. Phys. Lett. 99, p. 131909 (2011).
[4] J. Matthews and A. Blakeslee, J. Cryst. Growth 32 265 (1976).
[5] Manuscript entitled “Suppression of Relaxation in (2021) InGaN/GaN Laser Diodes using Limited Area Epitaxy” by Matthew T. Hardy, Shuji Nakamura, James S. Speck, and Steven P. DenBaars.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride based semiconductor device structure, comprising:
a substrate, or one or more III-nitride layers on the substrate, wherein:
the substrate or III-nitride layers include patterning that reduces crystal defects in subsequently deposited III-nitride device layers, as compared to crystal defects in III-nitride device layers deposited on an un-patterned substrate or un-patterned III-nitride layer, and
the III-nitride layers are semi-polar or non-polar layers.

2. The device of claim 1, further comprising the one or more III-nitride device layers above, below, or above and below, the III-nitride layers.

3. The device of claim 2, wherein the patterning includes one or more etched mesas.

4. The device of claim 2, wherein one or more of a thickness and composition of the III-nitride device layers are high enough such that a film, comprising one or more of the III-nitride layers and the III-nitride device layers, has a thickness near or greater than the film's critical thickness for relaxation without the patterning.

5. The device of claim 2, wherein the patterning comprises a hard mask.

6. The device of claim 5, wherein the III-nitride device layers are grown on an un-patterned region of the III-nitride layers or on an un-patterned region of the wafer comprising the substrate or the III-nitride layers.

7. The device of claim 1, wherein the patterning forms a pattern with one or more dimensions such that a thickness of one or more of the III-nitride device layers at a given composition, before relaxation, is increased by a factor of at least 4 as compared to without the patterning.

8. The device of claim 7, wherein the pattern comprises one or more stripes and a width of each of the stripes in the pattern is 1-50 μm.

9. The device of claim 2, wherein the patterning forms a pattern and an orientation of the pattern is such that a thickness of one or more of the III-nitride device layers at a given composition, before relaxation, is increased by a factor of at least 4.

10. The device of claim 2, wherein the patterning forms a pattern and the pattern is oriented parallel to an in-plane projection of a c-direction of the substrate or III-nitride layers.

11. The device of claim 2, wherein the patterning is performed on a layer subsequently grown on the substrate or the III-nitride layers.

12. The device of claim 2, wherein the patterning reduces or prevents the formation of misfit dislocation lines parallel to an a-direction of the III-nitride device layers.

13. The device of claim 2, wherein the patterning reduces or prevents the formation of misfit dislocation lines inclined with respect to an a-direction of the III-nitride device layers.

14. The device of claim 2, wherein the III-nitride device layers are the layers of a laser diode, including cladding layers, waveguiding layers and an active region.

15. The device of claim 2, wherein the III-nitride device layers are layers of a light emitting diode, solar cell or electronic device, such as a transistor.

16. The device of claim 2, wherein:
one or more of the III-nitride device layers above the patterning comprise a thickness greater than a thickness of similar III-nitride device layers deposited without the patterning, and
the device is a fully or partially coherent device with one or more of the III-nitride device layers thicker than a normal relaxation thickness limit.

17. The device of claim 1, wherein the patterning increases a thickness of a III-nitride device layer at a given composition, before relaxation, by a factor of at least 4.

18. The device of claim 2, wherein the III-nitride device layers comprise a quantum well active region with an indium composition of at least 30%, or an indium composition sufficient to emit light with a peak intensity corresponding to at least green light.

19. The device of claim 2, wherein:
the substrate is a Gallium Nitride substrate, and
the III-nitride device layers comprise:
n-type and p-type InGaN waveguiding layers that are coherently grown with a thickness of at least 100 nanometers and an Indium composition of at least 10%,
a multi quantum well active region, between the waveguiding layers, with InGaN quantum wells, wherein an indium composition of the quantum wells is at least 10%, and
n-type and p-type Gallium Nitride layers, wherein the n-type and p-type waveguiding layers are between the n-type and p-type GaN layers.

20. The device of claim 2, wherein:
the substrate is Gallium Nitride having a threading dislocation density of 10⁶ cm⁻² or more; and
the patterning is such that a misfit dislocation density in the III-nitride device layers is 10⁴ cm⁻² or less and located away from an active region of the device.

21. A method of fabricating a III-nitride based semiconductor device, comprising:
patterning a substrate, or one or more III-nitride layers on the substrate, to reduce crystal defects in subsequently deposited III-nitride device layers, as compared to crystal defects in III-nitride device layers deposited on an un-patterned substrate or un-patterned III-nitride layer; and
growing the III-nitride device layers on the patterned substrate or patterned III-nitride layers, wherein the III-nitride layers are semi-polar or non-polar layers.
